(19) United States
(12) Patent Application Publication
(10) Pub. No.: US 2025/0178267 A1
(43) Pub. Date: Jun. 5, 2025

(54) METHOD FOR PRODUCING SELECTIVELY METALLISED THREE-DIMENSIONAL ITEMS WITH A MASKING COATING COMPOSITION

(71) Applicant: JET METAL TECHNOLOGIES, CHAMPAGNE AU MONT D'OR (FR)

(72) Inventors: Samuel Paul Henry STREMSDOERFER, COLLONGES AU MONT D'OR (FR); Emilie LAI, BAGNOLET (FR)

(21) Appl. No.: 18/843,693

(22) PCT Filed: Mar. 3, 2023
(86) PCT No.: PCT/FR2023/050290

§ 371 Date: Sep. 3, 2024

(30) Foreign Application Priority Data
Mar. 4, 2022 (FR) FR2201908
Mar. 4, 2022 (FR) FR2201910

(51) Int. Cl. B29C 51/26; B29C 51/02; B29C 51/16; B29C 51/42; B29K 33/00; B29K 75/00; B29K 77/00; B29K 105/16; B29L 31/00; B29L 31/34

(52) U.S. Cl. CPC B29C 51/264; B29C 51/02; B29C 51/16; B29C 51/266; B29C 51/42; B29K 2033/08; B29K 2075/00; B29K 2077/00; B29K 2105/16; B29K 2995/0006; B29K 2995/0007; B29L 2031/3425; B29L 2031/3456; B29L 2031/779

(57) ABSTRACT

The invention relates to a composition for making a film-forming masking coating adhering to at least part of a surface of a substrate intended to be thermoformed for manufacturing a selectively metallized three-dimensional item, said composition comprising at least one organic polymer matrix formed of one or more organic monomers and/or polymers, said polymer matrix being curable to form said masking coating that, after curing, for a thickness of between 0.1 μm and 50 μm, has a deformation ratio at break higher than 30%, at a temperature of between 20° C. and 270° C.

The invention is particularly adapted for making a composition suitable for making a coating on the surface of a substrate intended to be thermoformed.

### TECHNICAL FIELD

The present invention relates to the general technical field of techniques and means for manufacturing three-dimensional items with metal pattern(s).

### PRIOR ART

In the field of printed electronics, it is known how to manufacture three-dimensional items or objects locally covered with electrically conductive metallizations, in which conductive patterns are produced on a thermoplastic polymer substrate by direct printing (screen or ink jet printing) using an electrically conductive ink, such as in particular an ink filled with silver particles. The substrate is then thermoformed to be given the desired three-dimensional aspect. In addition to the fact that implementing an electrically conductive ink is rather expensive, the electric performance of the conductive patterns obtained using such an ink can still be improved, particularly in terms of the level and homogeneity of electrical conductivity, which may in some cases prove problematic for the correct operation of an electronic device integrating such a three-dimensional object.

### DISCLOSURE OF THE INVENTION

The objects assigned to the invention therefore aim to provide a response to the above-mentioned needs and issues, in order to more simply, efficiently and economically manufacture three-dimensional items with decorative and/or functional metal pattern(s), in a wide variety of shapes and geometries.

Another object of the invention aims to enable easy manufacturing of three-dimensional items with metal pattern(s) of any size.

Another object of the invention aims to enable quick and relatively inexpensive manufacturing of three-dimensional items with metal pattern(s).

Another object of the invention aims to enable a simple manufacturing of three-dimensional items with metal pattern(s).

Another object of the invention aims to enable the manufacturing of three-dimensional items with metal pattern(s) with controlled manufacturing costs.

Another object of the invention aims to enable the manufacturing of three-dimensional items with metal pattern(s) in a wide variety of dimensions and shapes.

Another object of the invention aims to enable the manufacturing of three-dimensional items so that they have one (or more) fine, precise and/or complex metal pattern(s).

Another object of the invention aims to enable the manufacturing of three-dimensional items whose metal pattern(s) are particularly resistant to external aggressions.

Another object of the invention aims to enable the manufacturing of three-dimensional items whose metal pattern(s) are particularly homogeneous and regular, both in terms of thickness and surface appearance.

Another object of the invention aims to enable the manufacturing of three-dimensional items with metal pattern(s), with an excellent control over the shape of their metal pattern(s).

The objects assigned to the invention are achieved by means of a method for manufacturing a selectively metallized three-dimensional item, comprising at least:
a step of depositing a composition in the liquid or paste state onto a surface of a thermoformable substrate, said composition comprising at least one organic polymer matrix formed of one or more organic monomers and/or polymers, said composition comprising neither electrically conductive particles nor magnetic particles,
a step of curing said composition so deposited onto the substrate to form a film-forming masking coating adhering to the latter, said masking coating having a thickness of between 0.1 μm and 30 μm,
a step of thermoforming the substrate so coated with the film-forming masking coating,
a step of metallizing the substrate to form a metal deposit on the latter;
and a step of eliminating the masking coating using an alkaline solution, posteriorly or concomitantly to the substrate metallization step.

Hereafter is also described a composition for making a film-forming masking coating adhering to at least part of a surface of a substrate intended to be thermoformed for manufacturing a selectively metallized three-dimensional item, said composition comprising at least one organic polymer matrix formed of one or more organic monomers and/or polymers, said polymer matrix being curable to form said masking coating that, after curing, for a thickness of between 0.1 μm and 50 μm, has a deformation ratio at break higher than 30%, at a temperature of between 20° C. and 270° C.

Hereafter is also described a film-forming masking coating, made by depositing, onto a surface of a substrate intended to be thermoformed for manufacturing a selectively metallized three-dimensional item, of at least one layer of the composition according to the above, for example by screen printing and/or direct printing followed by a curing of said composition.

Hereafter is also described the use of a composition as mentioned hereinabove for making a film-forming masking coating on the surface of a thermoformable flat substrate.

Other features and advantages of the invention will appear in more detail upon reading of the following description.

### BEST WAY TO IMPLEMENT THE INVENTION

The invention relates, according to a first aspect, to a composition for making a film-forming masking coating adhering to at least part of the surface of a substrate. Said substrate is intended to be thermoformed for the manufacturing of a selectively metallized three-dimensional item. The composition of the invention is thus advantageously designed to be implemented in the manufacturing of a three-dimensional item comprising at least one metal pattern (or “metallized pattern”).

In the sense of the invention, “three-dimensional” means a physical object that expands substantially in the three dimensions of space, along distances that non-negligible from one another. The shape and sizes of the metal pattern(s) are not particularly limited, and may depend in particular on the intended application of the three-dimensional item and on the metal pattern(s) carried by the latter. Advantageously, the metal pattern(s) concerned are decorative and/or functional, and therefore form or contribute to form, for example and without limitation, one or more printed circuits, one or more printed circuits on a semi-conductive substrate, one or more sensor/detector electrodes, one or more electrodes of an electric heater/defroster device, one or more radio-frequency antennas (WiFi®, RFID, etc.), one or more encoding pictograms likely to be read by electronic devices, one or more figurative and/or scriptural information items identifying a product that incorporates or with which is associated said three-dimensional item, in particular a commercial product, such as a visual or decorative design on a packaging, on a car product, etc. The substrate is advantageously flat and thermoformable, in particular it is formed of one or more thermoplastic materials. Moreover, the masking coating is film-forming, i.e. it is advantageously suitable for making a coherent and/or continuous layer of material on a surface, and in particular on at least part of the surface of the substrate.

According to the invention, said composition comprises at least one organic polymer matrix formed of one or more organic monomers and/or polymers, said polymer matrix being curable to form said masking coating that, after curing, for a thickness of between 0.1 μm and 50 μm, has an elongation ratio at break higher than 30%, at a temperature of between 20° C. and 270° C.

The composition according to the invention can advantageously be implemented as follows for making a selectively metallized three-dimensional item:
application of the composition onto the surface of the substrate, which is thus advantageously flat and made of a thermoformable material (for example, a thermoplastic material), for example by screen printing and/or direct printing;
curing of the polymer matrix, thus forming the masking coating, which hence constitutes a film adhering to the substrate surface. The substrate thus has a masked area, i.e. an area covered with the masking coating, as well as an unmasked area, i.e. an area that is not covered with the masking coating;
thermoforming of the substrate to give the latter a generally three-dimensional shape;
metallization of the substrate to form a metal deposit on the latter, in particular in the unmasked area;
possibly, elimination of said masking coating, which is thus preferentially temporary, for example using an alkaline solution. The elimination of the masking coating may be posterior or concomitant to the substrate metallization.

Therefore, the invention further relates, in a second aspect, to a method for manufacturing a selectively metallized three-dimensional item. Obviously, the elements described for the composition described herein are advantageously also valid for the manufacturing method of the invention, and vice versa. The manufacturing method thus comprises a step of depositing a composition in the liquid or paste state onto a surface of a thermoformable substrate, said composition comprising at least one organic polymer matrix formed of one or more organic monomers and/or polymers. According to the second aspect of the invention, said composition comprises neither electrically conductive particles nor magnetic particles. The manufacturing method further comprises at least one step of curing said composition so deposited onto the substrate to form a film-forming masking coating adhering to the latter. In other words, at the end of the curing step, the masking coating advantageously adheres by bonding to at least part of the substrate surface, for example like a mask. Such bonding can be achieved without adding a sticky material distinct from the composition, the curing of the latter on the substrate in the curing step advantageously allowing the bonding of the so-formed masking coating to the substrate. The masking coating then preferably constitutes a layer of material covering (partly) said substrate and bonded to the latter, which will enable in particular to prevent metallization of the substrate surface covered with the masking coating during the metallization step as will be seen hereinafter.

According to the second aspect of the invention, said masking coating has a thickness of between 0.1 μm and 30 μm. The manufacturing method also comprises a step of thermoforming the substrate so coated with the film-forming masking coating.

Preferably, in the thermoforming step, the substrate is heated to a thermoforming temperature of between 20° C. and 270° C., preferably between 50° C. and 250° C., more preferentially between 70° C. and 230° C.

The unmasked area can for example be made by selectively applying the composition onto only a part of the substrate surface, which therefore constitutes the masked area, the other part then constituting the unmasked area. Alternatively, the unmasked area is made for example by mechanical removal of a portion of the coating (for example by cutting, scraping, etc.).

During the substrate thermoforming, preferably “at hot temperature” (e.g. a temperature of between 50° C. and 250° C.), i.e. during said thermoforming step, the masking coating, which thus covers a part of the substrate, undergoes a deformation as the latter. Thanks to its elongation capabilities, the masking coating adhering to the substrate keeps a great cohesion (without any significant “fracturing” of the coating), and above all does not “smudge” on the unmasked area of the substrate, which is subsequently selectively covered with a metal layer, for example by means of a spray, i.e. by spraying a metallization solution in the form of one or more aerosol(s) onto the substrate surface. The masked area of the substrate, being covered with the masking coating formed from said composition, is not covered with the metallization solution. In particular, the presence and possibly the elimination of said masking coating make it possible to quickly and economically obtain a particularly accurate metallized area (basically, the area non previous masked by the masking coating), without defect. The composition of the invention cleverly makes it possible to form a preferentially temporary (selective) masking coating adhering to the substrate surface, previously to the thermoforming of this substrate. For making a selective metallization of the substrate, it thus becomes advantageously possible to manufacture in a particularly simple and efficient way three-dimensional items with decorative and/or functional metal pattern(s), in a wide variety of shapes and geometries. Indeed, it is much easier in practice to make a (preferably temporary) masking on a (preferably flat) substrate than on a three-dimensional substrate, especially with a complex shape/geometry, and the use of such a (preferentially temporary) masking coating then enables to easily and accurately metallize a great variety of substrates of thermoformable material, according to a plurality of possible metallization techniques.

Therefore, according to the second aspect of the invention, the manufacturing method comprises at least:
a step of metallizing the substrate to form a metal deposit on the latter;
and a step of eliminating the masking coating using an alkaline solution, posteriorly or concomitantly to the substrate metallization step. Said alkaline (or basic) solution has a pH that is advantageously strictly greater than 7, more advantageously equal to or greater than 9.

Therefore, the masking coating is advantageously temporary, and intended to be removed before and/or during the selective metallization of the three-dimensional substrate, during said elimination step.

During said metallization step, the metal deposition is thus advantageously made only on a part of the substrate surface that is not covered with the masking coating. The metal deposit adheres to the substrate. When the masking coating is removed from the substrate during the elimination step, the substrate surface that was covered with the masking coating is thus preferably free, i.e. non covered, at least covered neither with the masking coating nor with the metal deposit.

The metal deposit is preferably made of solid metal. Thus, “metal deposit of solid metal” here advantageously means in particular that the metal deposit is advantageously devoid of polymer matrix. This enables in particular to obtain a metal pattern whose properties remain particularly stable over time, unlike a pattern comprising a polymer matrix in which metal particles would be dispersed, said polymer matrix being then likely to degrade progressively under the effect, for example, of light, heat, etc., thus leading to a drift in the metal pattern properties over time. Advantageously, the solid metal can be made of a single pure elementary metal (typically by more than 90%, preferably more than 95%, and still preferably more than 98%). For example, the metal deposit can thus be formed of a pure elementary metal, for example pure silver Ag (preferably, by more than 95%, and still preferably more than 98%), and possibly additional particles (e.g., particles of diamond carbon, particles of silicon carbide SiC, particles of molybdenum disulphide MoS₂, particles of one or more rare earth(s) or rare earth oxide(s), particles of graphene, particles of a fluoropolymer such as, e.g., polytetrafluoroethylene (PTFE), particles of an elementary metal or of metal oxide(s), etc.)

Advantageously, the metal deposit has, at the end of the metallization step, a thickness of between 10 nm and 5 μm, preferably between 10 nm and 1 μm, and still preferably between 10 nm and 500 nm. According to a variant, the metallization step is carried out so that the thickness of the metal deposit obtained at the end of the metallization step is substantially constant over the whole extend of said metal deposit, that is to say that the thickness is substantially the same at any point of the metal deposit. It is therefore possible to obtain one (or more) metal pattern(s) with a substantially constant thickness over the whole extent of the metal pattern(s). According to another variant, the metallization step is carried out so that the thickness of the metal deposit obtained at the end of the metallization step is variable over the extent of said metal deposit (while remaining preferentially in the above-mentioned ranges of values), that is to say the metal deposit has at least a first area and a second area, distinct from each other, the thickness of the metal deposit increasing or on the contrary decreasing (thickness gradient) from said first area to said second area. Such a thickness variation of the metal deposit thus advantageously enables to obtain one (or more) metal pattern(s) that define areas of different electrical conductivity or resistivity, or also of different transparency or reflectivity to electromagnetic waves (e.g. visible light, IR or UV, radio-frequency waves, etc.), which may be of particular interest depending on the intended functional and/or decorative applications.

Preferentially, said composition is designed to be liquid or pasty at the temperature at which it is applied onto the substrate, during said deposition step, and in particular is advantageously liquid or pasty at a temperature of between 20° C. and 50° C.

Advantageously, the organic polymer matrix and/or the masking coating is alkali-sensitive, and/or alkali-soluble, so that is can preferentially be dissolved by an alkaline solvent (i.e. with a pH strictly greater than 7).

According to a particular embodiment, compatible with the above, the organic polymer matrix and/or the coating is soluble and/or dispersible in a liquid, for example an aqueous solution, having a pH equal to or greater than 9.

The metallization solution can possibly dissolve the temporary masking coating during the substrate metallization. The metallization and elimination steps are then at least in part concomitant to each other. For example, during the spraying of the metallization solution in the form of aerosol(s), the unmasked area of the substrate is metallized, whereas the temporary masking coating is dissolved and evacuated by the effluent, letting appear the area previously masked by the masking coating.

In some cases, the masking coating may be intended to allow a selective activation of the substrate surface, so that, at the end of the elimination step, only at least one area of the substrate surface that is not masked by the masking coating is activated and able, during the metallization, to receive a metal deposit to form one or more metal pattern(s).

As a variant of the invention, the thermoforming step is carried out before the metallization step. As another variant of the invention, the thermoforming step is carried out after the metallization step.

The thermoforming step is preferentially carried out before the elimination step. This, of course, makes it possible to take advantage of the masking characteristics (non-metallization of the substrate areas that are masked by the coating) and elongation characteristics (during the substrate thermoforming) of the masking coating adhering to the substrate. Advantageously, during said thermoforming step, the substrate surface so covered with the masking coating is deformed.

Advantageously, the organic matrix comprises at least one monomer and/or polymer chosen among: acrylic compounds, polyesters, vinyl compounds, styrenic compounds, polyamides, acrylate compounds, and/or cationic or anionic polymers.

More precisely, said organic matrix preferentially comprises at least one or more of the following compounds: PETIA (pentaerythritol triacrylate), HDDA (hexanediol diacrylate), IBOA (isobornyl acrylate), TMPTA (trimethylolpropane triacrylate), TPGDA (tripropylene glycol diacrylate), HEMA (hydroxyethyl methacrylate), vinyl acetate and chloride copolymer, acrylic resin, polyvinyl alcohol, polyvinylpyrrolidone, polyurethane, styrene acrylic copolymer, aliphatic urethane acrylate, polyester acrylate, polyester, methyl methacrylate and ethyl acrylate copolymer, methyl methacrylate and butyl methacrylate copolymer, monofunctional acrylate monomer, and/or trifunctional acrylate monomer.

The exact nature of the organic matrix preferably depends at least in part on the nature of the substrate, and on the temperature for thermoforming the latter, and it is thus preferentially determined from the different characteristics of the coating and/or the composition exposed herein. The organic matrix provides important properties to the composition, such as its adhesion to the substrate, its resistance to friction, its ability to wet one or more potential solids in the composition, and more particularly its elongation capability (or deformation ratio), its ability to flow under the effect of heat and its sensitivity to alkaline products (advantageous when it is necessary to eliminate the coating after and/or during the substrate metallization).

The substrate is preferably made of a thermoformable polymer material (thermoplastic material), filled or not, or a composite polymer-matrix thermoformable material. Indeed, the polymer or polymer-matrix thermoformable materials are in particular generally easier to implement, due to a softening temperature fare less than that of glass or most of the metals. The possible thermoformable polymer materials forming the substrate include, by way of non-limiting examples, polystyrene (PS), “impact” polystyrene (SB/HIPS), polyethylene (PE), polypropylene (PP), polycarbonate (PC), acrylonitrile-butadiene-styrene (ABS), polyvinyl chloride (PVC), polymethyl methacrylate (PMMA), or thermoplastic polyesters, such as polylactic acid (PLA), polyethylene terephthalate (PET) and glycolyzed polyethylene terephthalate (PETG). In the case where the flat substrate is a composite polymer-matrix thermoformable material, the polymer(s) of the polymer matrix can be chosen, for example, among the thermoformable polymer materials listed hereinabove. More generally, the thermoformable material of the substrate can be a single material or on the contrary a composite material.

According to an advantageous variant of the second aspect of the invention, at the end of the deposition step and the curing step, the masking coating adheres to at least a first area of the substrate, whereas at the end of the metallization step and the elimination step, the metal deposit adheres to at least a second area and a third area of the substrate, separated from each other by said first area, no short-circuit or metal bridge connecting said second and third areas through said first area. Of course, said first, second and third areas are preferably distinct from each other. Said second and third areas are preferentially not adjacent, because they are separated from each other by said third area. One of the advantages of the invention, and more particularly of the manufacturing method, is to obtain an accurately metallized three-dimensional substrate, that is to say that the substrate has a metal pattern devoid of short-circuit, or metal bridge, undesirably connecting parts of the metal pattern, thus running the risk of short-circuiting it.

Advantageously, the composition is designed so that the coating has, for a thickness of between 0.1 μm and 30 μm of thickness, for example (approximately) equal to 5 μm of thickness (+/−1 μm), a deformation ratio at break higher than 100%, preferably higher than 300%, more preferentially higher than 600%, even more preferentially higher than 1,000%, at a temperature of between 20° C. and 270° C., preferably between 50° C. and 250° C., more preferentially between 70° C. and 230° C.

In other words, advantageously, at the thermoforming temperature (and for a thickness of between 0.1 μm and 30 μm of thickness), the masking coating has a deformation ratio at break that is (at least) higher than 30%. Advantageously, the deformation ratio at break is higher than 100%, preferentially higher than 300%, more preferentially higher than 600%, even more preferentially higher than 1,000%.

The deformation ratio measurement is advantageously made from a grid pattern thermoforming. According to a particular exemplary embodiment, a pattern of 5 mm squares formed by said composition, spaced apart by 300 μm, is screen printed onto an A4 size thermoformable substrate. The pattern appearing after curing and metallization is a grid of 300 μm wide lines. The substrate is thermoformed on various shapes of different heights. The sample is metallized and the coating is removed. The metallized grid makes it possible to quantify the deformation ratio that the masking coating can withstand. Thus, measuring the deformed square provides the elongation that the coating can withstand without affecting its ability to be removed within an alkaline environment. The measurement stops at the square in which a short-circuit exists between the parallel lines of the square.

The deformation ratio at break is calculated as follows:

$$( \frac{Width of the deformed square}{Intial width of the square} - 1 ) \times 100 = deformation ratio .$$

The distance is measured using a vernier caliper.

In more detail, the deformation ratio at break is preferentially measured using a test of thermoforming a substrate coated with a grid pattern of masking coating, where the steps of the manufacturing method are reproduced so that:
the deposition step and the curing step enable to obtain a substrate coated with the masking coating according to a pattern of masking coating squares, said squares being of same size and being regularly spaced apart by grid lines non covered with the masking coating, said squares being for example of 5 mm side and said grid lines being for example of 300 μm wide,
in the step of thermoforming the substrate so coated with the pattern of masking coating squares, the substrate is deformed into shapes of different heights, in order to obtain a pattern of deformed masking coating squares,
in the step of metallizing the substrate, the metal deposit is made on the substrate at said grid lines, to form metallized grid lines,
in the step of eliminating the masking coating, the pattern of deformed masking coating squares is removed from the substrate, to form a pattern of deformed substrate squares free from masking coating, said free deformed squares being separated from each other by the metallized grid lines;
the measurement of the deformation ratio at break is made from the free deformed square of smallest width in which a short-circuit or metal bridge exists between two non-secant, opposite metallized grid lines of said square, the deformation ratio at break being calculated as follows:

$$( \frac{Width of the ( free ) deformed square}{Intial width of the square} - 1 ) \times 100 = deformation ratio .$$

In other words, to evaluate the deformation ratio at break, squares of masking coating are made, regularly distributed on the substrate and bonded to the latter during the deposition and curing steps. The substrate areas that are not covered with the coating then form a grid comprising free grid lines, each square of masking coating on the substrate being surrounded by four grid lines, with the opposite lines parallel two-by-two and the secant lines perpendicular two-by-two. Said substrate is then hot-deformed in the thermoforming step, thus deforming the squares to obtain deformed masking coating squares. The deformed masking coating squares are then removed from the substrate in the elimination step and the substrate is metallized in the metallization step, so that a metal deposit is formed on the substrate surface and bonded to the latter only in the areas of the latter that have not been covered with the masking coating. The metal deposit then forms a metal grid adhering to the substrate, said metal grid comprising metallized grid lines. The metallized grid lines define a pattern of deformed substrate squares, said squares being free from masking coating at the end of the elimination step. For each free deformed square, short-circuit (also called “metal bridge”) must be avoided between to non-secant, opposite metallized grid lines on the surface of said square. Indeed, the presence of such a short-circuit or metal bridge means that, during the thermoforming step, the masking coating, having been stretched and deformed, has undergone a sufficiently large crack to allow metallization of the substrate at said crack (and hence at the free deformed square), thus connecting two opposite metallized grid lines, short-circuiting them in an undesirable manner. The free deformed square of smallest width including such a short-circuit or metal bridge is therefore selected as the measurement limit, and the width thereof is measured to be used in the above-mentioned formula. The metallization and elimination steps can be partly at least concomitant, or the metallization step can be carried out before the elimination step.

The masking coating is advantageously thermoformable, i.e. it preferentially has thermoplastic properties. Its thermoformable nature explains or contributes to explain its excellent elongation capabilities, i.e. its high ratio at break.

Advantageously, the organic polymer matrix forms between 20 and 80% of the total weight of the composition, although, in a particular alternative, it can form the totality or quasi-totality of the total weight of the composition.

Preferentially, the composition further comprises one or more solvents, said solvent(s) forming between 15 and 80% of the total weight of the composition, preferentially between 20 and 75% of the total weight of the composition, for example between 30 and 60% of the total weight of the composition. The solvent can advantageously, in the case of curing by thermal drying, be intended to be evaporated during the composition curing. The solvent advantageously allows the composition to have a liquid or paste state.

Said solvent(s) advantageously comprise at least one or more of the following compounds: isopropanol, butanol, methoxypropanol, ethyl acetate, butyl acetate, cyclohexane, 2-butoxyethanol acetate, 2-methoxy-1-methylethyl acetate, propylene carbonate, isopropyl myristate, diethylene glycol monoethyl ether acetate, glycerol, heavy naphtha, hexane, and/or methylcyclohexane.

According to a particular variant of the invention, said solvent(s) comprise at least water. When the composition comprises water, the latter optionally allows putting in solution a monomer or a polymer of the organic matrix, an additive or another solvent, or also constituting a dispersion medium.

Advantageously, the composition is devoid of metal and/or electrically conductive particles. In other words, the composition is designed so that the masking coating does not comprise any metal particles and/or electrically conductive particles. More precisely, neither the composition nor the coating contains solid, electrically conductive, metal particles, or only in low enough proportions so that the conductivity of the composition and/or the coating is very low, for example substantially of the same order of magnitude as that of an insulating material (e.g. polyethylene). In other words, the composition is preferentially designed so that the coating is electrically insulating and/or dielectric. The advantage of such a configuration is that the composition has a relatively low manufacturing cost, and that, in the case where it is not removed or not completely removed from the substrate, after and/or during the metallization, the coating, which is non-conductive, does not “interfere” with the metallized surface part of the three-dimensional thermoformed substrate.

Advantageously, the composition further comprises at least one dispersed organic or inorganic solid, said solid being preferably formed by powder particles dispersed within other constituents of said composition. This solid may give the composition its colour, part of its rheological properties and part its resistance to friction. Advantageously, said solid comprises a mineral filler, an organic filler and/or a fibrous filler. Said mineral, organic and/or fibrous filler is preferably in the form of multitude of small solid particles, advantageously in powder form. Said solid preferentially comprises at least one or more of the following compounds: silica, calcium carbonate, barium sulphate, aluminium hydroxide, and/or a wax. Said solid advantageously forms between 0.5 and 50%, preferably between 1 and 40%, more preferentially between 1.5 and 30%, even more preferentially between 2 and 20%, of the total weight of the composition.

The composition is advantageously designed so that the curing of the polymer matrix is made by (thermal) drying and/or application of UVs.

The curing of the polymer matrix advantageously corresponds to the polymerization and/or cross-linking of the latter.

Therefore, said composition comprises, according to a particular embodiment, at least one radical, cationic or anionic photo-initiator, advantageously capable of cross-linking part at least of the polymer matrix when the composition is subjected to ultra-violets. This is particularly advantageous when the curing of the composition is carried out using ultra-violets.

Advantageously, the photo-initiator agent forms between 0.5 and 15%, preferably between 1 and 10%, more preferentially between 1 and 7%, of the total weight of the composition. The photo-initiator agent advantageously comprises at least one of the following compounds: benzophenone, 1-hydroxy-cyclohexyl-phenyl-ketone, dimethylhydroxyacetophenone, diphenyl (2,4,6-trimethylbenzoyl) phosphine oxide, 1-chloro-4-propoxythioxanthone, 2,2-dimethoxy-1,2-phenylacetophenone.

The composition optionally comprises at least one or more of the following additional compounds: rheology agent, wetting agent, defoamer, dispersant, surfactant, stabiliser, colouring agent, amine synergist. The additional compound(s) preferentially form between 0.01 and 10% of the total weight of the composition.

Preferentially, the composition is designed so that the coating has a glass transition temperature and/or melting temperature below the glass transition temperature of the substrate.

The different compounds in the composition give it suitable characteristics for different applications on different substrates. An example of certain characteristics is illustrated in Table 1.

TABLE 1

| | Inkjet composition | | |
|---|---|---|---|
| | (a type of direct | Screen printing | Flexography |
| | printing) | composition | composition |
| Dynamic | 1 mPa · s to | Non-Newtonian: | Non-Newtonian: |
| viscosity | 1,000 mPa · s | 500 mPa · s to | 30 mPa · s to |
| at 25° C. | at 25° C., | 50,000 mPa · s, | 1,000 mPa · s, |
| | preferentially | preferentially between | preferentially |
| | between 1 mPa · s | 1,000 and 10,000 mPa · s, | between 30 mPa · s |
| | and 30 mPa · s with | more preferentially | and 500 mPa · s |
| | temperature rise | between 1,000 mPa · s | |
| | (in use) | and 5,000 mPa · s | |
| Surface | Between 10 mN/m | Not relevant | Between 10 mN/m |
| tension | and 72 mN/m | | and 72 mN/m |
| Particle or | Between | Between | Between |
| aggregate | 50 nm and 20 μm, | 50 nm and 100 μm, | 50 nm and 100 μm, |
| size, if present, | preferentially | more preferentially | more preferentially |
| and after | between | between | between |
| filtration (solid) | 70 nm and 5 μm, | 1 μm and 20 μm, | 500 nm and 20 μm, |
| | more preferentially | Even more preferentially | more preferentially |
| | between 100 nm | between 5 μm and 10 μm | between 1 μm |
| | and 500 nm | | and 5 μm |

For example, for an inkjet composition (“inkjet” being a type of direct printing), the desired dynamic viscosity at 25° C. is between 1 mPa·s and 1,000 mPa·s at 25° C., preferentially between 1 mPa·s and 30 mPa·s with temperature rise (in use), with a surface tension of between 10 mN/m and 72 mN/m, and a particle and aggregate size (i.e. in particular the solid(s)) of between 50 nm and 20 μm, preferentially between 70 nm and 5 μm, more preferentially between 100 nm and 500 nm.

The composition is preferably able to be applied on the substrate in any suitable way (depending on the substrate and the desired result), for example by screen printing, pad printing, flexography, rotogravure and/or direct printing (e.g. drip or “inkjet”). Thus, said deposition step is, according to an advantageous embodiment, carried out at least in part by screen printing and/or direct printing.

In a first example in accordance with the invention, given by way of illustration and without limitation, the composition comprises:
a polymer matrix formed i) of a methyl methacrylate and ethyl acrylate copolymer, said copolymer representing between 10% and 20% of the total weight of the composition, ii) of a methyl methacrylate and butyl methacrylate copolymer, said copolymer representing between 10% and 20% of the total weight of the composition, iii) a polyamide representing between 5% and 25% of the total weight of the composition, the polymer matrix thus representing between 25% and 65% of the total weight of the composition;
a solvent formed of a mixture of methoxypropanol and 2-butoxyethanol, said solvent representing between 30% and 75% of the total weight of the composition;
a solid in the form of a spherical organic filler (e.g. a powder), said solid representing between 2% and 10% of the total weight of the composition, and having a melting temperature of less than 110° C.;
a defoaming and spreading additive, representing between 1% and 5% of the total weight of the composition.

The composition of this first example is capable of undergoing a curing by (thermal) drying and can be applied onto the substrate using a screen printing mask.

In a second example in accordance with the invention, given by way of illustration and without limitation, the composition comprises:
a polymer matrix formed i) of a 35% solids aqueous polyurethane dispersion, the polyurethane (solid) representing between 10% and 25% of the total weight of the composition, ii) of a methyl methacrylate and ethyl acrylate copolymer, said copolymer representing between 10% and 20% of the total weight of the composition, ii) of trifunctional acrylate monomer representing between 5% and 20% of the total weight of the composition, iii) a monofunctional acrylate monomer representing between 5% and 15% of the total weight of the formulation, the polymer matrix thus representing between 20% and 60% of the total weight of the composition;
   a solvent formed of a mixture i) of the aqueous phase into which is dispersed polyurethane, and ii) of 2-butoxyethanol, said solvent representing between 20% and 60% of the total weight of the formula;
   a defoaming and spreading additive, representing between 1% and 5% of the total weight of the composition;
   a radical photo-initiator, representing between 1% and 7% of the total weight of the formulation.

The composition of this first example is capable of undergoing a curing by application of ultra-violets (UV) and can be applied onto the substrate in different ways (screen printing, direct printing, etc.).

According to a particular embodiment, the masking coating thickness has at least a first portion and a second portion, distinct from each other, the first portion thickness being different from the second portion thickness. In other words, the masking coating thickness may be variable according to the extent of the latter (while remaining preferentially in the above-mentioned ranges of values). Such a thickness difference of the masking coating, preferably in the ranges of values indicated hereinabove, can be interesting in certain embodiments, for example to adapt locally the masking coating thickness to the deformation ratio to which a given area of the substrate is to be subjected during the thermoforming of the latter.

According to a third aspect, the invention relates to a film-forming masking coating. This coating is made by deposition, onto a surface of a substrate intended to be thermoformed for manufacturing a selectively metallized three-dimensional item, of at least one layer of the composition as mentioned hereinabove, for example by screen printing and/or direct printing followed by curing of said composition. Said curing can advantageously be made by applying ultra-violets or by drying. The masking coating is preferentially, as indicated hereinabove, alkali-sensitive and/or alkali-soluble, and is advantageously dissolved and/or dispersed in a solution with a pH greater than or equal to 9. Obviously, the elements described for the above-described composition and method are advantageously also valid for the masking coating, and vice versa.

Preferably, the masking coating has a thickness of between 0.1 μm and 30 μm, preferably between 1 μm and 20 μm, still preferably between 3 μm and 10 μm. Such a thickness makes it possible to obtain a sufficient barrier effect at the surface of the substrate areas that are not intended to subsequently carry the metal pattern(s). Moreover, such a thickness advantageously contributes to the capacity of the masking coating to undergo the thermoforming without significant damage, as the case may be.

According to a fourth aspect, the invention relates to the use of a composition as mentioned hereinabove to make a (preferably, thermoformable) film-forming masking coating at the surface of a substrate intended to be thermoformed for manufacturing a selectively metallized three-dimensional item. Obviously, the elements described for the above-described composition, method and masking coatings are advantageously also valid for the above-mentioned use, and vice versa.

### POSSIBILITIES OF INDUSTRIAL APPLICATION

The invention finds an application in the general technical field of manufacturing three-dimensional items with decorative and/or functional metal pattern(s).

1. A method for manufacturing a selectively metallized three-dimensional item, comprising at least:
a step of depositing a composition in the liquid or paste state on a surface of a thermoformable substrate, said composition comprising at least one organic polymer matrix formed of one or more organic monomers and/or polymers, said composition comprising neither electrically conductive particles nor magnetic particles,
a step of curing said composition so deposited onto the substrate to form a film-forming masking coating adhering to the latter, said masking coating having a thickness of between 0.1 μm and 30 μm,
a step of thermoforming the substrate so coated with the film-forming masking coating,
a step of metallizing the substrate to form a metal deposit on the latter;
and a step of eliminating the masking coating using an alkaline solution, posteriorly or concomitantly to the substrate metallization step.

2. The manufacturing method according to claim 1, characterized in that, in the thermoforming step, the substrate is heated to a thermoforming temperature of between 20° C. and 270° C., preferably between 50° C. and 250° C., more preferentially between 70° C. and 230° C.

3. The manufacturing method according to claim 2, characterized in that, at the thermoforming temperature, the masking coating has a deformation ratio at break that is higher than 30%, the deformation ratio at break being measured using a test of thermoforming a substrate coated with a grid pattern of masking coating, where the steps of the manufacturing method are reproduced so that:
the deposition step and the curing step enable to obtain a substrate coated with the masking coating according to a pattern of masking coating squares, said squares being of same size and being regularly spaced apart by grid lines non covered with the masking coating, said squares being for example of 5 mm side and said grid lines being for example of 300 μm wide,
in the step of thermoforming the substrate so coated with the pattern of masking coating squares, the substrate is deformed into shapes of different heights, in order to obtain a pattern of deformed masking coating squares,
in the step of metallizing the substrate, the metal deposit is made on the substrate at said grid lines, to form metallized grid lines,
in the step of eliminating the masking coating, the pattern of deformed masking coating squares is removed from the substrate, to form a pattern of deformed substrate squares free from masking coating, said free deformed squares being separated from each other by the metallized grid lines;
the measurement of the deformation ratio at break is made from the free deformed square of smallest width in which a short-circuit or metal bridge exists between two non-secant, opposite metallized grid lines of said square, the deformation ratio at break being calculated as follows:
$$( \frac{Width of the deformed square}{Intial width of the square} - 1 ) \times 100 = deformation ratio .$$

4. The manufacturing method according to claim 3, characterized in that the deformation ration at break is higher than 100%, preferentially higher than 300%, more preferentially higher than 600%, even more preferentially higher than 1,000%.

5. The manufacturing method according to claim 1, characterized in that, at the end of the deposition step and the curing step, the masking coating adheres to at least a first area of the substrate, whereas at the end of the metallization step and the elimination step, the metal deposit adheres to at least a second area and a third area of the substrate, separated from each other by said first area, no short-circuit or metal bridge connecting said second and third areas through said first area.

6. The manufacturing method according to claim 1, characterized in that said organic matrix comprises at least one monomer and/or polymer chosen among: acrylic compounds, polyesters, vinyl compounds, styrenic compounds, polyamides, acrylate compounds, and/or cationic or anionic polymers.

7. The manufacturing method according to claim 1, characterized in that said organic matrix comprises at least one or more of the following compounds: PETIA (pentaerythritol triacrylate), HDDA (hexanediol diacrylate), IBOA (isobornyl acrylate), TMPTA (trimethylolpropane triacrylate), TPGDA (tripropylene glycol diacrylate), HEMA (hydroxyethyl methacrylate), vinyl acetate and chloride copolymer, acrylic resin, polyvinyl alcohol, polyvinylpyrrolidone, polyurethane, styrene acrylic copolymer, aliphatic urethane acrylate, polyester acrylate, polyester, methyl methacrylate and ethyl acrylate copolymer, methyl methacrylate and butyl methacrylate copolymer, monofunctional acrylate monomer, and/or trifunctional acrylate monomer.

8. The manufacturing method according to claim 1, characterized in that said organic matrix comprises at least a methyl methacrylate and ethyl acrylate copolymer, preferably forming between 10 and 20% of the total weight of the composition, a methyl methacrylate and butyl methacrylate copolymer, preferably forming between 10 and 20% of the total weight of the composition, and a polyamide, preferably forming between 5 and 25% of the total weight of the composition.

9. The manufacturing method according to claim 1, characterized in that said organic matrix comprises at least polyurethane, preferably forming between 10 and 25% of the total weight of the formulation, a trifunctional acrylate monomer preferably forming between 5 and 20% of the total weight of the composition, and a monofunctional acrylate monomer preferably forming between 5 and 15% of the total weight of the composition.

10. The manufacturing method according to claim 1, characterized in that the organic polymer matrix and/or the masking coating is alkali-sensitive.

11. The manufacturing method according to claim 1, characterized in that the organic polymer matrix and/or the coating is soluble and/or dispersible in a liquid, for example an aqueous solution, having a pH equal to or greater than 9.

12. The manufacturing method according to claim 1, characterized in that the organic polymer matrix forms between 20 and 80% of the total weight of the composition.

13. The manufacturing method according to claim 1, characterized in that the composition further comprises one or more solvents, said solvent(s) forming between 15 and 80% of the total weight of the composition, preferably between 20 and 75% of the total weight of the composition, for example between 30 and 60% of the total weight of the composition.

14. The manufacturing method according to claim 13, characterized in that said solvent(s) comprise at least one or more of the following compounds: isopropanol, butanol, methoxypropanol, ethyl acetate, butyl acetate, cyclohexane, 2-butoxyethanol acetate, 2-methoxy-1-methylethyl acetate, propylene carbonate, isopropyl myristate, diethylene glycol monoethyl ether acetate, glycerol, heavy naphtha, hexane, and/or methylcyclohexane.

15. The manufacturing method according to claim 13, characterized in that said solvent(s) comprise at least water.

16. The manufacturing method according to claim 1, characterized in that it is devoid of metal and/or electrically conductive particles.

17. The manufacturing method according to claim 1, characterized in that the coating is electrically insulating and/or dielectric.

18. The manufacturing method according to claim 1, characterized in that the composition further comprises at least one dispersed organic or inorganic solid, said solid being preferably formed by powder particles dispersed within other constituents of said composition.

19. The manufacturing method according to claim 18, characterized in that said solid comprises a mineral filler, an organic filler and/or a fibrous filler.

20. The manufacturing method according to claim 18, characterized in that said solid comprises at least one or more of the following compounds: silica, calcium carbonate, barium sulphate, aluminium hydroxide, and/or a wax.

21. The manufacturing method according to claim 18, characterized in that said solid forms between 0.5% and 50%, preferably between 1% and 40%, more preferably between 1.5% and 30%, even more preferably between 2% and 20% of the total weight of the composition.

22. The manufacturing method according to claim 1, characterized in that the composition comprises at least one radical, cationic or anionic photo-initiator, capable of cross-linking part at least of the polymer matrix when the composition is subjected to ultra-violets.

23. The coating manufacturing method according to claim 22, characterized in that the photo-initiator agent forms between 0.5% and 15%, preferably between 1% and 10%, more preferentially between 1 and 7%, of the total weight of the composition.

24. The coating manufacturing method according to claim 22, characterized in that the photo-initiator agent comprises at least one of the following compounds: benzophenone, 1-hydroxy-cyclohexyl-phenyl-ketone, dimethylhydroxyacetophenone, diphenyl (2,4,6-trimethylbenzoyl) phosphine oxide, 1-chloro-4-propoxythioxanthone, 2,2-dimethoxy-1,2-phenylacetophenone.

25. The manufacturing method according to claim 1, characterized in that the composition comprises at least one or more of the following additional compounds: rheology agent, wetting agent, defoamer, dispersant, surfactant, stabiliser, colouring agent, amine synergist.

26. The manufacturing method according to claim 25, characterized in that the additional compound(s) form between 0.01% and 10% of the total weight of the composition.

27. The manufacturing method according to claim 26, characterized in that the masking coating has a glass transition temperature and/or melting temperature below the glass transition temperature of the substrate.

28. The manufacturing method according to claim 1, characterized in that said deposition step is carried out at least in part by screen printing and/or direct printing.

29. The manufacturing method according to claim 1, characterized in that the masking coating has a thickness of between 1 μm and 20 μm, preferably between 3 μm and 10 μm.

30. The manufacturing method according to claim 1, characterized in that the masking coating has at least a first portion and a second portion, distinct from each other, the first portion thickness being different from the second portion thickness.

31. The manufacturing method according to claim 1, characterized in that, in said thermoforming step, the substrate surface so covered with the masking coating is deformed.

32. The manufacturing method according to claim 1, characterized in that the thermoforming step is carried out before the metallization step.

33. The method according to claim 1, characterized in that the thermoforming step is carried out after the metallization step.

34. The manufacturing method according to claim 1, characterized in that the thermoforming step is carried out before the elimination step.

35. The method according to claim 1, characterized in that the metal deposit is made of solid metal.

36. The method according to claim 1, characterized in that the metal deposit has, at the end of the metallization step, a thickness of between 10 nm and 5 μm, preferably between 10 nm and 1 μm, and still preferably between 10 nm and 500 nm.
